(19) United States
(12) Patent Application Publication
(10) Pub. No.: US 2026/0144123 A1
(43) Pub. Date: May 21, 2026

(54) SEMICONDUCTOR DEVICES AND METHODS OF MANUFACTURING THE SAME

(71) Applicant: Samsung Electronics Co., Ltd., Suwon-si (KR)

(72) Inventors: JUNHONG MIN, Suwon-si (KR); SEOKHO KIM, Suwon-si (KR); HOJIN LEE, Suwon-si (KR)

(21) Appl. No.: 19/323,278

(22) Filed: Sep. 9, 2025

(30) Foreign Application Priority Data
Nov. 20, 2024 (KR) 10-2024-0166606

(51) Int. Cl. H01L 23/00; H01L 25/18; H10B 80/00; H10D 80/30

(52) U.S. Cl. CPC H10W 72/90; H10W 72/019; H10W 99/00; H10B 80/00; H10D 80/30; H10W 72/01935; H10W 72/01951; H10W 72/923; H10W 72/942; H10W 72/952; H10W 80/312; H10W 80/327; H10W 90/00; H10W 90/792

(57) ABSTRACT

A semiconductor device includes a first stack structure including a first substrate, a first bonding layer on the first substrate, and a first bonding pad extending into the first bonding layer; and a second stack structure on the first stack structure, wherein the second stack structure includes a second substrate, a second bonding layer on the second substrate, and a second bonding pad extending into the second bonding layer, wherein the first bonding layer includes a first lower bonding layer and a first upper bonding layer extending around the first bonding pad, wherein the second bonding layer includes a second lower bonding layer and a second upper bonding layer extending around the second bonding pad, wherein the first bonding layer contacts the second bonding layer, and wherein the first bonding pad contacts the second bonding pad.

### CROSS-REFERENCE TO RELATED APPLICATIONS

This application is based on and claims priority under 35 U.S.C. § 119 to Korean Patent Application No. 10-2024-0166606, filed on Nov. 20, 2024, in the Korean Intellectual Property Office, the disclosure of which is incorporated by reference herein in its entirety.

### BACKGROUND OF THE INVENTION

The inventive concept relates to semiconductor devices and methods of manufacturing the same, and more particularly, to semiconductor devices based on hybrid copper bonding and methods of manufacturing the semiconductor devices.

In the field of electronic products, the demand for portable devices is increasing, and thus, there is ongoing demand for size reduction (e.g., the miniaturization) and weight reduction of electronic components included in electronic products. To realize size reduction and weight reduction of electronic components, semiconductor devices included in electronic components may need to have a smaller volume and process high quantities of data. In manufacturing a semiconductor device, substrates may be bonded to each other for various purposes (for example, for increasing the degree of integration or enhancing performance). Copper (Cu) pads formed on an upper surface of each wafer may be bonded to each other, for an electrical connection between substrates.

### SUMMARY OF THE INVENTION

The inventive concept provides semiconductor devices including a bonding layer comprising (or consisting of) a double layer having different compositions (e.g., different element ratios) and methods of manufacturing the semiconductor devices.

The object of the inventive concept is not limited to the aforesaid, but other objects not described herein will be understood by those of ordinary skill in the art from descriptions below.

A semiconductor device according to an embodiment includes a first stack structure that includes a first substrate, a first bonding layer on the first substrate, and a first bonding pad that extends into the first bonding layer; and a second stack structure on the first stack structure, wherein the second stack structure includes a second substrate, a second bonding layer on the second substrate, and a second bonding pad that extends into the second bonding layer, wherein the first bonding layer includes a first lower bonding layer and a first upper bonding layer that extend around the first bonding pad, wherein the second bonding layer includes a second lower bonding layer and a second upper bonding layer that extend around the second bonding pad, wherein the first bonding layer of the first stack structure is in contact with the second bonding layer of the second stack structure, and wherein the first bonding pad of the first stack structure is in contact with the second bonding pad of the second stack structure.

A semiconductor device according to an embodiment includes a first stack structure and a second stack structure on the first stack structure, wherein the first stack structure comprises: a first substrate; a first wiring structure that is on an upper surface of the first substrate and includes a plurality of first wiring layers and a plurality of first insulation layers that are respectively on the plurality of first wiring layers; a first bonding layer that includes a first lower bonding layer and a first upper bonding layer, wherein the first lower bonding layer is on an upper surface of the first wiring structure, and the first upper bonding layer is on an upper surface of the first lower bonding layer; and a first bonding pad that passes through the first bonding layer, wherein the second stack structure comprises: a second substrate; a second wiring structure that is on a lower surface of the second substrate and includes a plurality of second wiring layers and a plurality of second insulation layers that are respectively on the plurality of second wiring layers; a second bonding layer that includes a second lower bonding layer and a second upper bonding layer, wherein the second lower bonding layer is on a lower surface of the second wiring structure, and the second upper bonding layer is on a lower surface of the second lower bonding layer; and a second bonding pad that passes through the second bonding layer, wherein the first upper bonding layer of the first stack structure is in contact with the second upper bonding layer of the second stack structure, and wherein the first bonding pad of the first stack structure is in contact with the second bonding pad of the second stack structure.

A method of manufacturing a semiconductor device according to an embodiment includes forming, on a first substrate, a first lower bonding layer that includes a first material and a first upper bonding layer that includes a second material on the first lower bonding layer, wherein the first material has a first composition that is different from a second composition of the second material; forming a first opening that extends into the first lower bonding layer and the first upper bonding layer; forming a first metal layer in the first opening and on the first upper bonding layer; planarizing the first metal layer to form a first bonding pad; forming, on a second substrate, a second lower bonding layer that includes a third material and a second upper bonding layer that includes a fourth material on the second lower bonding layer, wherein the third material has a third composition that is different from a fourth composition of the fourth material; forming a second opening that extends into the second lower bonding layer and the second upper bonding layer; forming a second metal layer in the second opening and on the second upper bonding layer; planarizing the second metal layer to form a second bonding pad; and bonding the first upper bonding layer and first bonding pad to the second upper bonding layer and the second bonding pad.

### BRIEF DESCRIPTION OF THE DRAWINGS

Embodiments will be more clearly understood from the following detailed description taken in conjunction with the accompanying drawings in which:

FIG. 1 is a cross-sectional view illustrating a schematic configuration of a semiconductor device according to some embodiments;

FIG. 2 is an enlarged cross-sectional view of a region EX1 of FIG. 1;

FIGS. 3 to 7 are cross-sectional views sequentially illustrating a method of manufacturing a semiconductor device, according to some embodiments;

FIG. 8 is a cross-sectional view illustrating a schematic configuration of a semiconductor package according to some embodiments;

FIG. 9 is a cross-sectional view illustrating a schematic configuration of a semiconductor device according to some embodiments;

FIG. 10 is an enlarged cross-sectional view of a region EX2 of FIG. 9;

FIG. 11 is a perspective view illustrating a schematic configuration of a semiconductor device according to some embodiments;

FIG. 12 is a cross-sectional view taken along line A1-A1′ of FIG. 1;

FIG. 13 is an enlarged cross-sectional view of a region EX3 of FIG. 12; and

FIG. 14 is a cross-sectional view illustrating a schematic configuration of a semiconductor device according to some embodiments.

### DETAILED DESCRIPTION OF THE INVENTION

Hereinafter, embodiments will be described in detail with reference to the accompanying drawings. Like reference numerals refer to like elements in the drawings, and their repeated descriptions may be omitted.

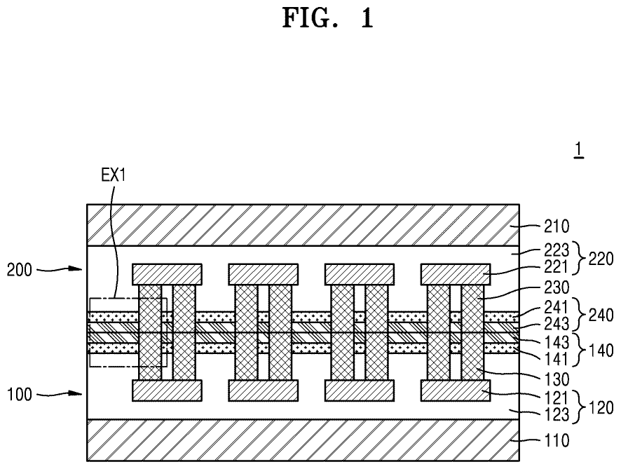

FIG. 1 is a cross-sectional view illustrating a schematic configuration of a semiconductor device 1 according to some embodiments.

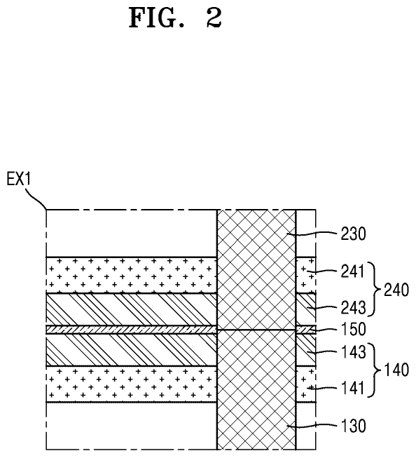

FIG. 2 is an enlarged cross-sectional view of a region EX1 of FIG. 1.

Referring to FIGS. 1 and 2, the semiconductor device 1 according to some embodiments may include a first stack structure 100 and a second stack structure 200 (on the first stack structure 100). The semiconductor device 1 according to some embodiments may have a structure where the second stack structure 200 is bonded to the first stack structure 100.

In embodiments, the first stack structure 100 may include a first substrate 110, a first wiring structure 120, a first bonding layer 140, and a plurality of first bonding pads 130. The first wiring structure 120 may be on (e.g., cover or overlap in a vertical direction) an upper surface of the first substrate 110, and the first bonding layer 140 may be on (e.g., cover or overlap in the vertical direction) an upper surface of the first wiring structure 120. That is, the first bonding layer 140 may be disposed apart from the first substrate 110 in the vertical direction with the first wiring structure 120 therebetween, but an embodiment is not limited thereto. The vertical direction may be perpendicular to the upper surface of the first substrate 110 and/or the upper surface of the first wiring structure 120. As used herein, the term “and/or” includes any and all combinations of one or more of the associated listed items. Expressions such as “at least one of,” when preceding a list of elements, modify the entire list of elements and do not modify the individual elements of the list.

In embodiments, the first substrate 110 may include, for example, a semiconductor element such as silicon (Si) and/or germanium (Ge). The first substrate 110 may include a compound semiconductor such as silicon carbide (SiC), gallium arsenide (GaAs), indium arsenide (InAs), and/or indium phosphide (InP). In some embodiments, the first substrate 110 may have a silicon on insulator (SOI) structure. The first substrate 110 may include a buried oxide (BOX) layer. The first substrate 110 may include a conductive region (for example, an impurity-doped well) or an impurity-doped structure. The first substrate 110 may include various device isolation structures such as a shallow trench isolation (STI) structure.

In embodiments, the first substrate 110 may include a first circuit layer, and the first circuit layer may be provided on or close to an upper surface of the first substrate 110. The first circuit layer may include an element such as a transistor.

In embodiments, the first wiring structure 120 may be provided in (or on the upper surface of) the first substrate 110. The first wiring structure 120 may include a plurality of first wiring layers 121 and a first insulation layer(s) 123. The first insulation layer(s) 123 may be on (e.g., cover or extend around) the plurality of first wiring layers 121. In this case, the first wiring layers 121 may include a plurality of wiring vias and a plurality of wiring lines, and the plurality of wiring vias and the plurality of wiring lines may comprise (or consist of) a multilayer to be disposed at a plurality of vertical levels and may be electrically connected to each other. The plurality of first wiring layers 121 may include, for example, copper (Cu), aluminum (Al), tungsten (W), titanium (Ti), titanium nitride (TiN), tantalum (Ta), tantalum nitride (TaN), ruthenium (Ru), and/or tungsten nitride (WN). Herein, the term “level”, “vertical level”, “height”, or the like may refer to a relative location with respect to a reference element in the vertical direction. For example, a level, a vertical level, height, or the like may be a distance from a lower surface of the first substrate 110 in the vertical direction. For example, a higher level may mean a farther distance from the lower surface of the first substrate 110 in the vertical direction, and a lower level may mean a closer distance to the lower surface of the first substrate 110 in the vertical direction.

In embodiments, the first insulation layer(s) 123 may include a single insulation layer or a plurality of insulation layers. The first insulation layer(s) 123 may include, for example, silicon oxide (SiO₂) and/or silicon nitride (SiN). According to some embodiments, an uppermost layer of the first insulation layer(s) 123 may be a layer including SiO₂.

In embodiments, the first bonding layer 140 may comprise (or consist of) a double layer (e.g., two sub-layers). The first bonding layer 140 may include a first lower bonding layer 141 and a first upper bonding layer 143 (on the first lower bonding layer 141). The first lower bonding layer 141 may be on (e.g., cover or overlap in the vertical direction) an upper surface of the first wiring structure 120, and the first upper bonding layer 143 may be on (e.g., cover or overlap in the vertical direction) an upper surface of the first lower bonding layer 141.

In embodiments, the first lower bonding layer 141 and the first upper bonding layer 143 may include different materials (e.g., materials having different compositions (e.g., different element ratios). The first lower bonding layer 141 and the first upper bonding layer 143 may include SiCN, and the first lower bonding layer 141 and the first upper bonding layer 143 may differ in composition (e.g., element ratio). For example, the first lower bonding layer 141 may include C-rich SiCN, and the first upper bonding layer 143 may include N-rich SiCN.

In embodiments, the first lower bonding layer 141 including C-rich SiCN may denote more including carbon (C) than SiCN of a bonding layer according to a comparative example. The first upper bonding layer 143 including N-rich SiCN may denote more including nitrogen (N) than SiCN of the bonding layer according to the comparative example.

In embodiments, a ratio of carbon (C) to nitrogen (N) included in each of the first lower bonding layer 141 and the first upper bonding layer 143 may differ. For example, a composition (e.g., an element ratio) of SiCN of the bonding layer according to the comparative example may be about Si:C:N=45:20:35. In this case, a composition (e.g., an element ratio) of SiCN of the first lower bonding layer 141 may be about Si:C:N=40:30:30. A composition (e.g., an element ratio) of SiCN of the first upper bonding layer 143 may be about Si:C:N=40:20:40. That is, the first lower bonding layer 141 may denote a region (a layer) where a ratio of carbon (C) is relatively higher than the first upper bonding layer 143, and the first upper bonding layer 143 may denote a region (a layer) where a ratio of nitrogen (N) is relatively higher than the first lower bonding layer 141.

In embodiments, a thickness of the first lower bonding layer 141 may be greater (thicker) than that of the first upper bonding layer 143 (in the vertical direction). For example, a thickness of the first lower bonding layer 141 may be (about) 500 nm to (about) 700 nm, and a thickness of the first upper bonding layer 143 may be (about) 300 nm to (about) 500 nm.

In embodiments, the plurality of first bonding pads 130 may extend into (e.g., pass through) the first bonding layer 140 (in the vertical direction). The plurality of first bonding pads 130 may be surrounded by the first bonding layer 140. The first bonding layer 140 may extend around (e.g., at least partially surround) the plurality of first bonding pads 130. The plurality of first bonding pads 130 may include, for example, copper, but is not limited thereto.

In embodiments, an upper surface of the first bonding layer 140 and upper surfaces of the first bonding pads 130 may configure a coplanar surface. For example, an upper surface of the first upper bonding layer 143 and the upper surfaces of the first bonding pads 130 may configure a coplanar surface. A cavity may be formed between the first bonding pads 130 and the first bonding layer 140. In this case, the cavity may denote an empty space formed between the first bonding pads 130 and the first bonding layer 140.

In embodiments, the second stack structure 200 may include a second substrate 210, a second wiring structure 220, a second bonding layer 240, and a plurality of second bonding pads 230. The second wiring structure 220 may be on (e.g., cover or overlap in the vertical direction) a lower surface of the second substrate 210, and the second bonding layer 240 may be on (e.g., cover or overlap in the vertical direction) a lower surface of the second wiring structure 220. That is, the second bonding layer 240 may be disposed apart from the second substrate 210 in the vertical direction with the second wiring structure 220 therebetween, but an embodiment is not limited thereto.

In embodiments, the second substrate 210 may include, for example, a semiconductor element such as Si and/or Ge. The second substrate 210 may include a compound semiconductor such as SiC, GaAs, InAs, and/or InP. The second substrate 210 may have an SOI structure. The second substrate 210 may include a BOX layer. The second substrate 210 may include a conductive region (for example, an impurity-doped well) or an impurity-doped structure. The second substrate 210 may include various device isolation structures such as an STI structure.

In embodiments, the second substrate 210 may include a second circuit layer, and the second circuit layer may be provided in (or on or close to a lower surface of) the second substrate 210. The second circuit layer may include an element such as a transistor.

In embodiments, the second wiring structure 220 may be provided on the lower surface of the second substrate 210. The second wiring structure 220 may include a plurality of second wiring layers 221 and second insulation layer(s) 223. The second insulation layer(s) 223 may be on (e.g., cover or extend around) the plurality of second wiring layers 221. In this case, the second wiring layer 221 may include a plurality of wiring vias and a plurality of wiring lines, and the plurality of wiring vias and the plurality of wiring lines may comprise (or consist of) a multilayer to be disposed at a plurality of vertical levels and may be electrically connected to each other. The plurality of second wiring layers 221 may include, for example, Cu, Al, W, Ti, TiN, Ta, TaN, Ru, and/or WN.

In embodiments, the second insulation layer(s) 223 may include a single insulation layer or a plurality of insulation layers. The second insulation layer(s) 223 may include SiO₂ and/or SiN. According to some embodiments, a lowermost layer of the second insulation layer(s) 223 may be a layer including SiO₂.

In embodiments, the second bonding layer 240 may comprise (or consist of) a double layer (e.g., two sub-layers). The second bonding layer 240 may include a second lower bonding layer 241 and a second upper bonding layer 243 (on the second lower bonding layer 241). The second lower bonding layer 241 may be on (e.g., cover or overlap in the vertical direction) a lower surface of the second wiring structure 220, and the second upper bonding layer 243 may be on (e.g., cover or overlap in the vertical direction) a lower surface of the second lower bonding layer 241.

In embodiments, the second lower bonding layer 241 and the second upper bonding layer 243 may include different materials (e.g., materials having different compositions (e.g., different element ratios)). The second lower bonding layer 241 and the second upper bonding layer 243 may include SiCN, and the second lower bonding layer 241 and the second upper bonding layer 243 may differ in composition (e.g., element ratio). For example, the second lower bonding layer 241 may include C-rich SiCN, and the second upper bonding layer 243 may include N-rich SiCN.

In embodiments, the second lower bonding layer 241 including C-rich SiCN may denote more including carbon (C) than SiCN of the bonding layer according to the comparative example. The second upper bonding layer 243 including N-rich SiCN may denote more including nitrogen (N) than SiCN of the bonding layer according to the comparative example.

In embodiments, a ratio of carbon (C) to nitrogen (N) included in each of the second lower bonding layer 241 and the second upper bonding layer 243 may differ. For example, a composition (e.g., an element ratio) of SiCN of the bonding layer according to the comparative example may be about Si:C:N=45:20:35. In this case, a composition (e.g., an element ratio) of SiCN of the second lower bonding layer 241 may be about Si:C:N=40:30:30. A composition (e.g., an element ratio) of SiCN of the second upper bonding layer 243 may be about Si:C:=40:20:40. That is, the second lower bonding layer 241 may denote a region (a layer) where a ratio of carbon (C) is relatively higher than the second upper bonding layer 243, and the second upper bonding layer 243 may denote a region (a layer) where a ratio of nitrogen (N) is relatively higher than the second lower bonding layer 241.

In embodiments, a thickness of the second lower bonding layer 241 may be greater (thicker) than that of the second upper bonding layer 243 (in the vertical direction). For example, a thickness of the second lower bonding layer 241 may be (about) 500 nm to (about) 700 nm, and a thickness of the second upper bonding layer 243 may be (about) 300 nm to (about) 500 nm.

In embodiments, the plurality of second bonding pads 230 may extend into (e.g., pass through) the second bonding layer 240 (in the vertical direction). The plurality of second bonding pads 230 may be surrounded by the second bonding layer 240. The second bonding layer 240 may extend around (e.g., at least partially surround) the plurality of second bonding pads 230. The plurality of second bonding pads 230 may include, for example, copper, but is not limited thereto.

In embodiments, a lower surface of the second bonding layer 240 and lower surfaces of the second bonding pads 230 may configure a coplanar surface. For example, a lower surface of the second upper bonding layer 243 and the lower surfaces of the second bonding pads 230 may configure a coplanar surface. A cavity may be formed between the second bonding pads 230 and the second bonding layer 240. In this case, the cavity may denote an empty space formed between the second bonding pads 230 and the second bonding layer 240.

In embodiments, the first stack structure 100 may contact the second stack structure 200. In detail, the first bonding layer 140 of the first stack structure 100 and the second bonding layer 240 of the second stack structure 200 may be disposed to overlap each other in the vertical direction and may be adhered to each other. The first bonding pads 130 of the first stack structure 100 and the second bonding pads 230 of the second stack structure 200 may be disposed to overlap each other in the vertical direction and may be adhered to each other. The first bonding pads 130 and the second bonding pads 230 may include, for example, copper. That is, the first stack structure 100 and the second stack structure 200 may be bonded to each other by, for example, a hybrid copper bonding (HCB) process. In this case, a bonding interface layer 150 may be disposed between the first bonding layer 140 and the second bonding layer 240. The bonding interface layer 150 may include oxide and may be less (e.g., thinner) in thickness (in the vertical direction) than the first bonding layer 140 and the second bonding layer 240.

In embodiments, in the semiconductor device 1, each of the first bonding layer 140 and the second bonding layer 240 each disposed on an interface (e.g., the bonding interface layer 150) between the first stack structure 100 and the second stack structure 200 may comprise (or consist of) a double layer (two sub-layers). In this case, each of the first upper bonding layer 143 and the second upper bonding layer 243 bonded to each other may include N-rich SiCN which is low (e.g., lower than the first lower bonding layer 141 and the second lower bonding layer 241) in chemical mechanical polishing (CMP) removal rate, and thus, a CMP process step may be easily controlled. Each of the first lower bonding layer 141 and the second lower bonding layer 241 may include C-rich SiCN, and thus, may absorb a gas occurring from each of the first upper bonding layer 143 and the second upper bonding layer 243 each including N-rich SiCN in a thermal treatment process, thereby reducing (e.g., preventing) a stripping defect of the semiconductor device 1. Accordingly, the reliability of the semiconductor device 1 may be enhanced, and structural stability may increase.

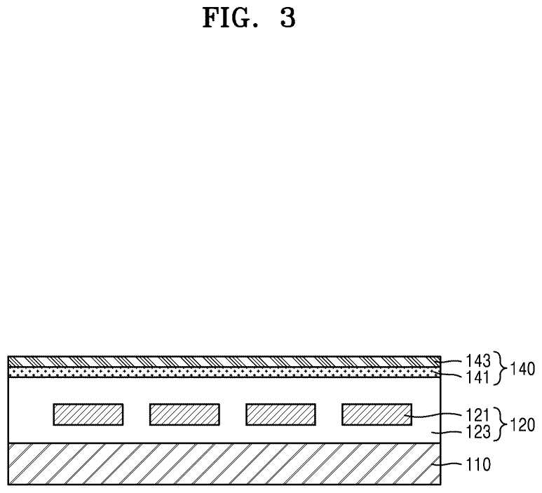

FIGS. 3 to 7 are cross-sectional views illustrating a method of manufacturing a semiconductor device in order, according to some embodiments. In providing description with reference to FIGS. 3 to 7, like reference numerals may refer to like elements, and their detailed descriptions may be omitted.

Referring to FIG. 3, a first wiring structure 120 may be formed on a first substrate 110, and a first bonding layer 140 may be formed on the first wiring structure 120. In this case, the first wiring structure 120 may include a plurality of first wiring layers 121, including a plurality of wiring vias and a plurality of wiring lines, and a first insulation layer(s) 123.

A first lower bonding layer 141 may be formed on the first wiring structure 120, and a first upper bonding layer 143 may be formed on the first lower bonding layer 141. In this case, the first lower bonding layer 141 and the first upper bonding layer 143 may include different materials (e.g., materials having different compositions (e.g., different element ratios). The first lower bonding layer 141 and the first upper bonding layer 143 may include SiCN, and the first lower bonding layer 141 and the first upper bonding layer 143 may differ in composition (e.g., element ratio). For example, the first lower bonding layer 141 may include C-rich SiCN, and the first upper bonding layer 143 may include N-rich SiCN.

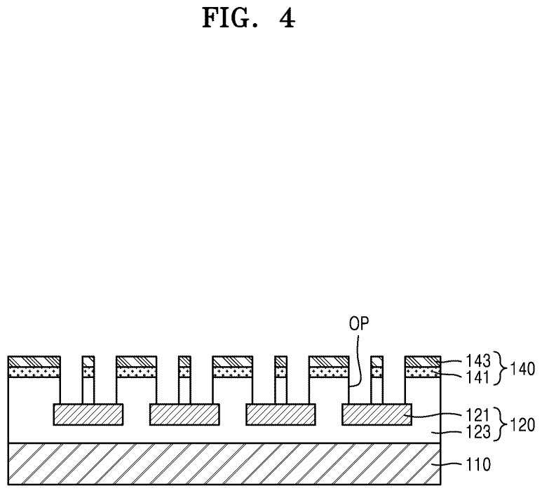

Referring to FIG. 4, a plurality of openings OP extending into (e.g., passing through) the first bonding layer 140 and a portion of the first wiring structure 120 may be formed from an upper surface of the first upper bonding layer 143. A photoresist pattern (not shown) may be formed on the upper surface of the first upper bonding layer 143, and the plurality of openings OP may be formed by using the photoresist pattern as an etch mask. At this time, the plurality of openings OP may expose (at least) a portion of the first wiring layer 121.

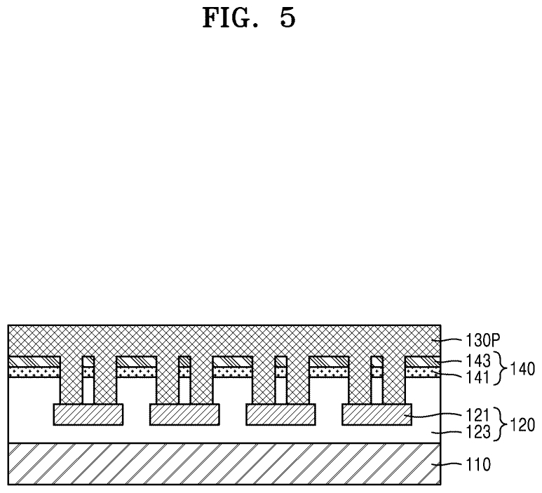

Referring to FIG. 5, a metal layer 130P on (e.g., covering or overlapping) the plurality of openings OP (see FIG. 4) and the first upper bonding layer 143 may be formed. For example, a barrier layer on (e.g., conformally covering or overlapping) the plurality of openings OP and the first upper bonding layer 143 may be formed, and a seed layer on (e.g., covering or overlapping) the barrier layer may be formed. In this case, the barrier layer may include a stack structure of one material or two or more materials, for example, Ti, Ta, and/or TiN, and the seed layer may include, for example, copper. The metal layer 130P may be formed from the seed layer through, for example, an electroplating process. The barrier layer may perform a function of reducing (e.g., preventing) the diffusion of copper from the metal layer 130P. However, the method of forming the metal layer 130P is not limited to the description above.

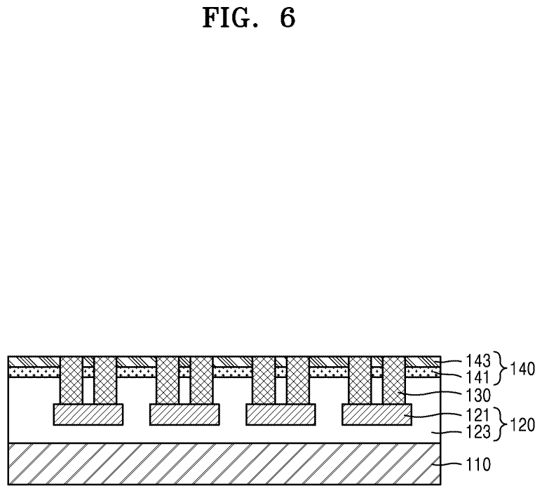

Referring to FIG. 6, first bonding pads 130 may be formed by performing a planarization process. For example, a portion (e.g., an upper portion) of the metal layer 130P (see FIG. 5) (and a portion of the first upper bonding layer 143) may be removed by a CMP process. Upper surfaces of the first bonding pads 130 and an upper surface of the first upper bonding layer 143 may configure a coplanar surface through the planarization process. In this case, the first upper bonding layer 143 may include N-rich SiCN which is low in CMP removal rate, and thus, a CMP process step may be easily controlled. The first lower bonding layer 141 may include C-rich SiCN, and thus, may absorb a gas occurring from the first upper bonding layer 143 including N-rich SiCN in a thermal treatment process.

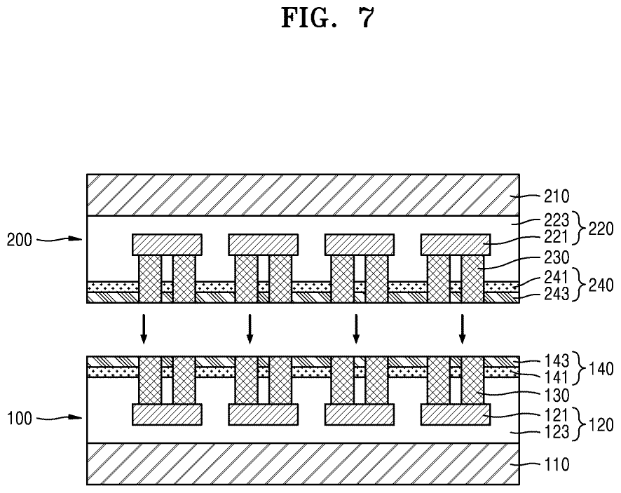

Referring to FIG. 7, the second stack structure 200 may be formed through the method described above with reference to FIGS. 3 to 6. Subsequently, the second stack structure 200 may be bonded to the first stack structure 100. The first bonding layer 140 of the first stack structure 100 and the second bonding layer 240 of the second stack structure 200 may be disposed to overlap each other in the vertical direction and may be adhered to each other. The first bonding pads 130 of the first stack structure 100 and the second bonding pads 230 of the second stack structure 200 may be disposed to overlap each other in the vertical direction and may be adhered to each other. At this time, the first stack structure 100 and the second stack structure 200 may be bonded to each other by an HCB process.

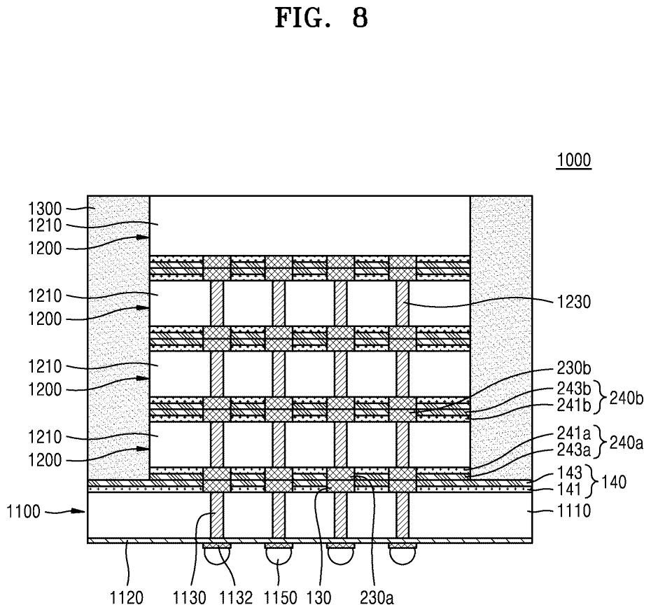

FIG. 8 is a cross-sectional view illustrating a schematic configuration of a semiconductor package 1000 according to some embodiments. In providing description with reference to FIG. 8, a first bonding layer 140 and second bonding layers 240a and 240b may be (substantially) the same as the first bonding layer 140 and the second bonding layer 240 each described above with reference to FIGS. 1 to 7.

Referring to FIG. 8, the semiconductor package 1000 according to some embodiments may include a base chip 1100, a plurality of semiconductor chips 1200, a first bonding layer 140, a plurality of second bonding layers 240a and 240b, and an encapsulation layer 1300.

In embodiments, the base chip 1100 may include a semiconductor material such as a Si wafer. The base chip 1100 may have a width (in a horizontal direction that is parallel with an upper surface and/or a lower surface of the first semiconductor substrate 1110). which is greater than the plurality of semiconductor chips 1200.

In embodiments, the base chip 1100 may include a first semiconductor substrate 1110, a first front-side structure 1120, first bonding pads 130, a first bonding layer 140, and first through vias 1130. In this case, the first through vias 1130 may denote a through silicon via (TSV), but are not limited thereto. Lower bumps 1150 may be disposed under the base chip 1100 (e.g., the first semiconductor substrate 1110). The lower bumps 1150 may be (electrically) connected to the first front-side pads 1132 and may be electrically connected to the base chip 1100.

In embodiments, the base chip 1100 may be, for example, a buffer chip which includes a plurality of logic devices and/or memory devices disposed in the first front-side structure 1120. Therefore, the base chip 1100 may transfer a signal, received from each of the plurality of semiconductor chips 1200 stacked in an upper portion, to the outside through the lower bump 1150, and may transfer power and a signal from the outside to the plurality of semiconductor chips 1200. The base chip 1100 may perform a logic function and a memory function through the logic devices and the memory devices, but is not limited thereto and may include only the logic devices and may thus perform only the logic function. In some embodiments, the base chip 1100 may be an interposer with the plurality of semiconductor chips 1200 mounted thereon. As used hereinafter, the terms “external/outside configuration”, “external/outside device”, “external/outside power”, “external/outside signal”, or “outside” are intended to broadly refer to a device, circuit, block, module, power, and/or signal that resides externally (e.g., outside of a functional or physical boundary) with respect to a given circuit, block, module, system, or device.

In embodiments, the first semiconductor substrate 1110 may include a semiconductor element such as Si and/or Ge. The first semiconductor substrate 1110 may include a compound semiconductor such as SiC, GaAs, InAs, or InP. The first semiconductor substrate 1110 may have an SOI structure. The first semiconductor substrate 1110 may include a BOX layer. The first semiconductor substrate 1110 may include a conductive region (for example, an impurity-doped well) or an impurity-doped structure. The first semiconductor substrate 1110 may include various device isolation structures such as an STI structure.

In embodiments, the first front-side structure 1120 may be disposed on a lower surface of the first semiconductor substrate 1110 and may include various kinds of elements. For example, the first front-side structure 1120 may include a field effect transistor (FET) such as a planar FET and a FinFET, memory devices such as flash memory, dynamic random access memory (DRAM), static random access memory (SRAM), electrically erasable programmable read-only memory (EEPROM), phase-change random access memory (PRAM), magnetoresistive random access memory (MRAM), ferroelectric random access memory (FeRAM), and resistive random access memory (RRAM), logic devices such as an AND gate, an OR gate, and a NOT gate, and various active devices and/or passive devices such as system large scale integration (LSI), image sensors such as CMOS imaging sensor (CIS), and micro-electro-mechanical system (MEMS).

In embodiments, the first front-side structure 1120 may include a plurality of multi-layer wiring layers electrically connected to the devices and a plurality of interlayer insulation layers. The wiring layers may electrically connect the devices with each other, or may electrically connect the devices to the conductive region of the first semiconductor substrate 1110, or may electrically connect the devices to the lower bumps 1150. In this case, the first front-side structure 1120 may be protected as a separate passivation layer including, for example, silicon oxide, silicon nitride, and/or silicon oxynitride.

In embodiments, the lower bumps 1150 may be disposed on the first front-side pads 1132 and may be electrically connected to the first through vias 1130 or the wiring layers of the first front-side structure 1120. The lower bumps 1150 may each be configured as a solder ball, but are not limited thereto. For example, the lower bumps 1150 may have a structure including a pillar and a solder. The semiconductor package 1000 may be mounted on an external substrate such as a main board through the lower bumps 1150.

In embodiments, the first bonding layer 140 may be on (e.g., cover or overlap in the vertical direction) an upper surface of the first semiconductor substrate 1110 and may comprise (or consist of) a double layer (e.g., two sub-layers). The first bonding layer 140 may include a first lower bonding layer 141 and a first upper bonding layer 143. The first lower bonding layer 141 may be on (e.g., cover or overlap in the vertical direction) an upper surface of the first semiconductor substrate 1110, and the first upper bonding layer 143 may be on (e.g., cover or overlap in the vertical direction) an upper surface of the first lower bonding layer 141.

In embodiments, the first lower bonding layer 141 and the first upper bonding layer 143 may include different materials (e.g., materials having different compositions (e.g., different element ratios). The first lower bonding layer 141 and the first upper bonding layer 143 may include SiCN, and the first lower bonding layer 141 and the first upper bonding layer 143 may differ in composition (e.g., element ratio). For example, the first lower bonding layer 141 may include C-rich SiCN, and the first upper bonding layer 143 may include N-rich SiCN.

In embodiments, the plurality of first bonding pads 130 may extend into (e.g., pass through) the first bonding layer 140. The plurality of first bonding pads 130 may be surrounded by the first bonding layer 140. The first bonding layer 140 may extend around (e.g., at least partially surround) the plurality of first bonding pads 130. The plurality of first bonding pads 130 may include, for example, copper.

In embodiments, the first through vias 1130 may vertically extend into (e.g., pass through) the first semiconductor substrate 1110 and may provide an electrical path which (electrically) connects the first front-side pads 1132 to the first bonding pads 130. Each of the first through vias 1130 may include a conductive plug and a barrier layer extending around (e.g., at least partially surrounding) the conductive plug.

In embodiments, the plurality of semiconductor chips 1200 may be stacked on the base chip 1100. The plurality of semiconductor chips 1200 may be sequentially stacked in a vertical direction on the base chip 1100 to configure a stack structure.

In embodiments, each of the plurality of semiconductor chips 1200 may include a second semiconductor substrate 1210, a second front-side structure (not shown), a plurality of second upper bonding pads 230b, a plurality of second lower bonding pads 230a, a plurality of second bonding layers 240a and 240b, and a plurality of second through vias 1230. In a semiconductor chip 1200 disposed in an uppermost portion among the plurality of semiconductor chips 1200, second through vias may be omitted. In this case, the second through vias 1230 may each be a TSV, but are not limited thereto. The plurality of semiconductor chips 1200 may be electrically connected to each other through the second upper bonding pads 230b and the second lower bonding pads 230a (and the second through vias 1230).

In embodiments, the second semiconductor substrate 1210 may include a semiconductor element such as Si and/or Ge. The second semiconductor substrate 1210 may include a compound semiconductor such as SiC, GaAs, InAs, and/or InP. The second semiconductor substrate 1210 may have an SOI structure. The second semiconductor substrate 1210 may include a BOX layer. The second semiconductor substrate 1210 may include a conductive region (for example, an impurity-doped well) and/or an impurity-doped structure. The second semiconductor substrate 1210 may include various device isolation structures such as an STI structure.

In embodiments, the second front-side structure may include a plurality of memory devices. For example, the second front-side structure may include volatile memory devices such as DRAM and SRAM and/or non-volatile memory devices such as PRAM, MRAM, FeRAM, and RRAM. The second front-side structure may include a plurality of multi-layer wiring layers electrically connected to the memory devices and the interlayer insulation layers.

In embodiments, the second bonding layers 240a and 240b may be on (e.g., cover or overlap in the vertical direction) an upper surface or a lower surface of the second semiconductor substrate 1210 and may each comprise (or consist of) a double layer (e.g., two sub-layers). The second bonding layers 240a and 240b may respectively include second lower bonding layers 241a and 241b and second upper bonding layers 243a and 243b. The second lower bonding layers 241a and 241b may be on (e.g., cover or overlap in the vertical direction) the upper surface or the lower surface of the second semiconductor substrate 1210, and the second upper bonding layers 243a and 243b may be respectively on (e.g., cover or overlap in the vertical direction) upper surfaces or lower surfaces of the second lower bonding layers 241a and 241b.

In embodiments, the second lower bonding layers 241a and 241b and the second upper bonding layers 243a and 243b may include different materials (e.g., materials having different compositions (e.g., different element ratios)). The second lower bonding layers 241a and 241b and the second upper bonding layers 243a and 243b may include SiCN, and the second lower bonding layers 241a and 241b and the second upper bonding layers 243a and 243b may differ in composition (e.g., element ratio). For example, the second lower bonding layers 241a and 241b may include C-rich SiCN, and the second upper bonding layers 243a and 243b may include N-rich SiCN.

In embodiments, the second lower bonding pads 230a and the second upper bonding pads 230b may respectively extend into (e.g., pass through) the second bonding layers 240a and 240b. The second lower bonding pads 230a and the second upper bonding pads 230b may be respectively surrounded by the second bonding layers 240a and 240b. The second bonding layers 240a and 240b may respectively extend around (e.g., at least partially surround) the second lower bonding pads 230a and the second upper bonding pads 230b. The second lower bonding pads 230a and the second upper bonding pads 230b may include, for example, copper.

In embodiments, the base chip 1100 may be bonded to the plurality of semiconductor chips 1200. In detail, the first bonding layer 140 of the base chip 1100 and the second bonding layer 240a of the semiconductor chip 1200 disposed at a lowermost end may be disposed to overlap each other in the vertical direction and may be adhered to each other. In detail, the first bonding pads 130 of the base chip 1100 and the second lower bonding pads 230a of the semiconductor chip 1200 disposed at a lowermost end may be disposed to overlap each other in the vertical direction and may be adhered to each other. The second bonding layers 240a and 240b of the semiconductor chips 1200 disposed adjacent to each other (in the vertical direction) may be disposed to overlap each other in the vertical direction and may be adhered to each other. The second lower bonding pads 230a and the second upper bonding pads 230b of the semiconductor chips 1200 disposed adjacent to each other may be disposed to overlap each other in the vertical direction and may be adhered to each other. The base chip 1100 and the plurality of semiconductor chips 1200 may be bonded to each other by an HCB process.

In embodiments, the base chip 1100 may include a plurality of logic devices and/or memory devices in the first front-side structure 1120 and may be referred to as a buffer chip or a control chip, based on functions, and each of the plurality of semiconductor chips 1200 may include a plurality of memory devices in the second front-side structure and may be referred to as a core chip. The base chip 1100 and the plurality of semiconductor chips 1200 may configure a high bandwidth memory (HBM). For example, the base chip 1100 may be a buffer chip for the control of HBM DRAM, and the plurality of semiconductor chips 1200 may be a memory cell chip including a cell of HBM DRAM controlled by the base chip 1100. The base chip 1100 may be referred to as a buffer chip, a master chip, or an HBM controller die, and the plurality of semiconductor chips 1200 may be referred to as a memory chip, a slave chip, a DRAM dice, or a DRAM slice. The base chip 1100 and the plurality of semiconductor chips 1200 may be referred to as an HBM DRAM device or an HBM DRAM chip.

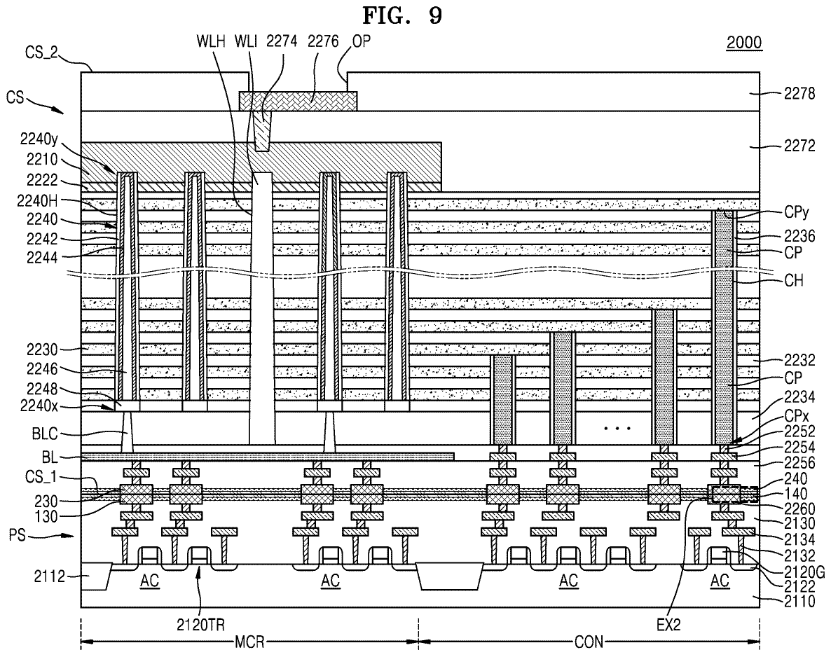

FIG. 9 is a cross-sectional view illustrating a schematic configuration of a semiconductor device 2000 according to some embodiments.

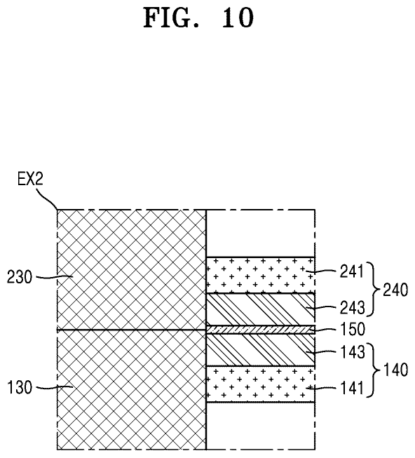

FIG. 10 is an enlarged cross-sectional view of a region EX2 of FIG. 9.

Referring to FIGS. 9 and 10, the semiconductor device 2000 may include a cell structure CS and a peripheral circuit structure PS, which overlap each other in a vertical direction. The cell structure CS may include a plurality of memory cell blocks. Each of the plurality of memory cell blocks may include memory cells which are three-dimensionally arranged. In providing description with reference to FIGS. 9 and 10, a first bonding layer 140 and a second bonding layer 240 may be (substantially) the same as the first bonding layer 140 and the second bonding layer 240 each described above with reference to FIGS. 1 to 7.

In embodiments, the peripheral circuit structure PS may include a peripheral circuit transistor 2120TR disposed on (in) a substrate 2110. An active region AC may be defined by a device isolation layer 2112 in the substrate 2110, and a plurality of peripheral circuit transistors 2120TR may be formed on the active region AC. The plurality of peripheral circuit transistors 2120TR may include a peripheral circuit gate 2120G and a source/drain region 2122 disposed at a portion of the substrate 2110 at both (e.g., opposite) sides of the peripheral circuit gate 2120G.

In embodiments, the substrate 2110 may include a semiconductor material, and for example, may include Group IV semiconductor, Group III-V compound semiconductor, and/or Group II-VI oxide semiconductor. For example, the Group IV semiconductor may include Si, Ge, and/or silicon germanium (SiGe). The substrate 2110 may be provided as a bulk wafer or an epitaxial layer. In embodiments, the substrate 2110 may include a silicon-on-insulator (SOI) substrate or a germanium-on-insulator (GeOI) substrate.

In embodiments, a plurality of peripheral circuit contacts 2132 and a plurality of peripheral circuit wiring layers 2134 may be disposed on an upper surface of the substrate 2110. An interlayer insulation layer 2130 on (e.g., covering or extending around) the peripheral circuit transistor 2120TR, the plurality of peripheral circuit contacts 2132, and the plurality of peripheral circuit wiring layers 2134 may be disposed on the substrate 2110. The plurality of peripheral circuit wiring layers 2134 may have a multi-layer structure including a plurality of metal layers disposed at different vertical levels. A plurality of first bonding pads 130 and a first bonding layer 140 on (e.g., covering, overlapping, or extending around) the plurality of first bonding pads 130 may be disposed on the interlayer insulation layer 2130. The first bonding layer 140 may include a first lower bonding layer 141 and a first upper bonding layer 143. The first lower bonding layer 141 may be on (e.g., cover or overlap in the vertical direction) an upper surface of the interlayer insulation layer 2130, and the first upper bonding layer 143 may be on (e.g., cover or overlap in the vertical direction) an upper surface of the first lower bonding layer 141.

In embodiments, the first lower bonding layer 141 and the first upper bonding layer 143 may include different materials (e.g., materials having different compositions (e.g., different element ratios)). The first lower bonding layer 141 and the first upper bonding layer 143 may include SiCN, and the first lower bonding layer 141 and the first upper bonding layer 143 may differ in composition (e.g., element ratio). For example, the first lower bonding layer 141 may include C-rich SiCN, and the first upper bonding layer 143 may include N-rich SiCN.

In embodiments, the plurality of first bonding pads 130 may extend into (e.g., pass through) the first bonding layer 140. The plurality of first bonding pads 130 may be surrounded by the first bonding layer 140. The first bonding layer 140 may extend around (e.g., at least partially surround) the plurality of first bonding pads 130. The plurality of first bonding pads 130 may include, for example, copper.

In embodiments, the cell structure CS may include a first surface CS_1 connected to the peripheral circuit structure PS and a second surface CS_2 opposite to the first surface CS_1 (in the vertical direction). In the drawing, it is illustrated that the first surface CS_1 of the cell structure CS is disposed at a lower side of the cell structure CS, and the second surface CS_2 of the cell structure CS is disposed at an upper side of the cell structure CS.

In embodiments, gate electrodes 2230 may be disposed apart from each other in a vertical direction in a cell region MCR and a connection region CON, and the gate electrodes 2230 and mold insulation layers 2232 may be alternately arranged (in the vertical direction). The gate electrodes 2230 may include, for example, metal such as tungsten, nickel, cobalt, and/or tantalum, metal silicide such as tungsten silicide, nickel silicide, cobalt silicide, and/or tantalum silicide, doped polysilicon, and/or a combination thereof.

A stack isolation insulation layer WLI may be disposed in a stack isolation opening portion WLH which extend into (e.g., passes through) the gate electrodes 2230 and the mold insulation layers 2232 and extends in a vertical direction. The stack isolation insulation layer WLI may include an upper surface disposed at a vertical level which is higher than an uppermost gate electrode 2230 and may protrude upward with respect to the uppermost gate electrode 2230. In some embodiments, gate electrodes 2230 disposed between a pair of stack isolation opening portions WLH (in the horizontal direction) may configure one block.

In embodiments, a channel structure 2240 may be disposed in a channel hole 2240H which extends into (e.g., passes through) the gate electrodes 2230 and the mold insulation layers 2232 and extends in a vertical direction. The channel structure 2240 may include a gate insulation layer 2242, a channel layer 2244, a buried insulation layer 2246, and a drain region 2248. The gate insulation layer 2242, the channel layer 2244, and the buried insulation layer 2246 may be sequentially arranged on an inner wall of the channel hole 2240H.

In embodiments, the drain region 2248 electrically connected to the channel layer 2244 may be disposed at a first end portion 2240x of the channel structure 2240. The drain region 2248 may be (electrically) connected to a bit line contact BLC, and the channel layer 2244 may be electrically connected to the bit line BL through the drain region 2248 and the bit line contact BLC. In a second end portion 2240y of the channel structure 2240, an upper surface of the channel layer 2244 may not be covered by the gate insulation layer 2242, and a common source layer 2210 may be (electrically) connected to the upper surface of the channel layer 2244.

In embodiments, an etch stop layer 2222 may be disposed on the uppermost gate electrode 2230, and the etch stop layer 2222 may include, for example, polysilicon. In some embodiments, the etch stop layer 2222 may be omitted.

In some embodiments, the common source layer 2210 may be (electrically) connected to the second end portion 2240y of the channel structure 2240 and may be conformally formed to be on (e.g., to cover or overlap) an upper surface of the stack isolation insulation layer WLI, on the etch stop layer 2222. In a one-dimensional viewpoint, the common source layer 2210 may be disposed in an entire region of the cell region MCR.

In embodiments, the common source layer 2210 may include silicon (Si), germanium (Ge), silicon germanium (SiGe), gallium arsenide (GaAs), indium gallium arsenide (InGaAs), aluminum gallium arsenide (AlGaAs), and/or a compound thereof. The common source layer 2210 may include a semiconductor doped with n-type impurities. The common source layer 2210 may have a crystalline structure including crystalline, amorphous, and polycrystalline. However, the crystallin structure and materials of the common source layer 2210 are not limited to the descriptions above.

In embodiments, a connection via 2252, a connection wiring layer 2254, and an interlayer insulation layer 2256 extending around (e.g., at least partially surrounding) the connection via 2252 and the connection wiring layer 2254 may be disposed between a stack cover insulation layer 2234 and the peripheral circuit structure PS. The connection via 2252 and the connection wiring layer 2254 may comprise (or consist of) a multilayer to be disposed at a plurality of vertical levels. A plurality of second bonding pads 230 and a second bonding layer 240 extending around (e.g., covering or overlapping) the plurality of second bonding pads 230 may be disposed on the interlayer insulation layer 2256. The second bonding layer 240 may include a second lower bonding layer 241 and a second upper bonding layer 243. The second lower bonding layer 241 may be on (e.g., cover or overlap in the vertical direction) a lower surface of the interlayer insulation layer 2256, and the second upper bonding layer 243 may be on (e.g., cover or overlap in the vertical direction) a lower surface of the second lower bonding layer 241.

In embodiments, the second lower bonding layer 241 and the second upper bonding layer 243 may include different materials (e.g., materials having different compositions (e.g., different element ratios)). The second lower bonding layer 241 and the second upper bonding layer 243 may include SiCN, and the second lower bonding layer 241 and the second upper bonding layer 243 may differ in composition (e.g., element ratio). For example, the second lower bonding layer 241 may include C-rich SiCN, and the second upper bonding layer 243 may include N-rich SiCN.

In embodiments, the plurality of second bonding pads 230 may extend into (e.g., pass through) the second bonding layer 240. The plurality of second bonding pads 230 may be surrounded by the second bonding layer 240. The second bonding layer 240 may extend around (e.g., at least partially surround) the plurality of second bonding pads 230. The plurality of second bonding pads 230 may include, for example, copper.

In embodiments, the peripheral circuit structure PS may be bonded to the cell structure CS. In detail, the first bonding layer 140 of the peripheral circuit structure PS and the second bonding layer 240 of the cell structure CS may be disposed to overlap each other in a vertical direction and may be adhered to each other. The first bonding pads 130 of the peripheral circuit structure PS and the second bonding pads 230 of the cell structure CS may be disposed to overlap each other in a vertical direction and may be adhered to each other. The peripheral circuit structure PS and the cell structure CS may be bonded to each other by an HCB process. The peripheral circuit structure PS may be electrically connected and bonded to the cell structure CS by the first bonding pads 130 and the second bonding pads 230. In this case, a bonding interface layer 150 may be disposed between the first bonding layer 140 and the second bonding layer 240 (in the vertical direction). The bonding interface layer 150 may include, for example, oxide and may be less (thinner) in thickness than the first bonding layer 140 and the second bonding layer 240.

In embodiments, the plurality of gate electrodes 2230 may extend in a horizontal direction in the cell region MCR and the connection region CON. The plurality of gate electrodes 2230 may overlap each other in a vertical direction in the connection region CON.

In embodiments, the plurality of contact plugs CP may extend into (e.g., pass through) the stack cover insulation layer 2234, the mold insulation layer 2232, and the gate electrodes 2230 and may extend in a vertical direction in the connection region CON. The plurality of contact plugs CP may have a height which varies in a vertical direction. In embodiments, each of the plurality of contact plugs CP may include a first end portion CPx and a second end portion CPy, the first end portions CPx of the plurality of contact plugs CP may be disposed at the same vertical level, and the second end portions CPy of the plurality of contact plugs CP may be disposed at different vertical levels, and for example, each of the second end portions CPy of the plurality of contact plugs CP may be (electrically) connected to a corresponding gate electrode 2230.

In embodiments, an upper surface of each of the plurality of contact plugs CP may contact a corresponding gate electrode 2230, and thus, one contact plug CP may be electrically connected to a corresponding gate electrode 2230. In embodiments, a sidewall of each of the plurality of contact plugs CP may be (at least partially) surrounded by an insulation spacer 2236.

In embodiments, the contact plugs CP may include, for example, metal such as tungsten, nickel, cobalt, and/or tantalum, metal silicide such as tungsten silicide, nickel silicide, cobalt silicide, and/or tantalum silicide, doped polysilicon, and/or a combination thereof. The insulation spacer 2236 may include silicon oxide.

In embodiments, an upper insulation layer 2272 may be disposed on the common source layer 2210. The upper insulation layer 2272 may include a flat surface in all of the cell region MCR and the connection region CON. A common source contact 2274, which extend into (e.g., passes through) the upper insulation layer 2272 and is (electrically) connected to the common source layer 2210, may be provided, and a backside wiring layer 2276 electrically connected to the common source contact 2274 may be disposed on the upper insulation layer 2272. A passivation layer 2278 on (e.g., covering or overlapping) the backside wiring layer 2276 may be disposed on the upper insulation layer 2272. The passivation layer 2278 may include an opening portion OP which exposes an upper surface of the backside wiring layer 2276.

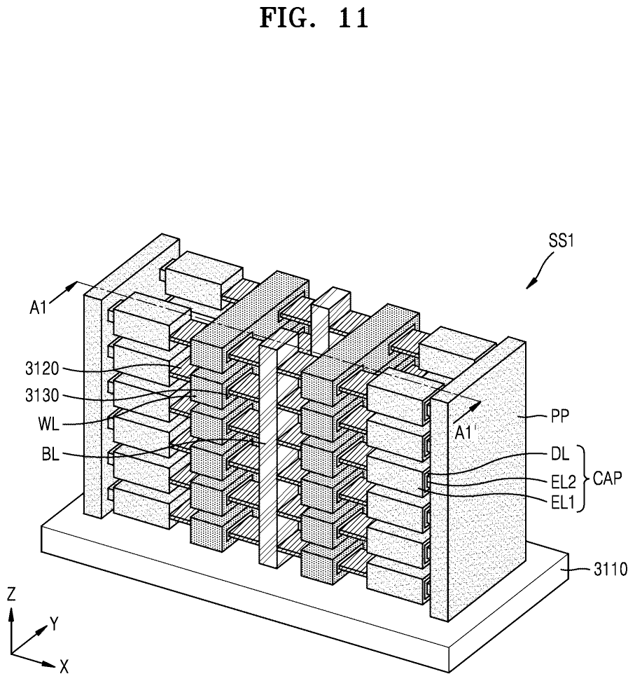

FIG. 11 is a perspective view illustrating a schematic configuration of a semiconductor device 3000 according to some embodiments.

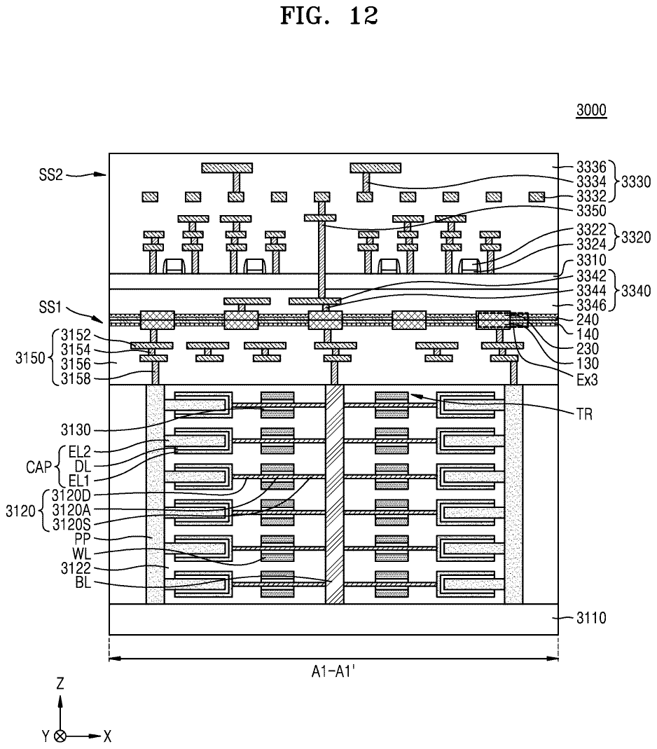

FIG. 12 is a cross-sectional view taken along line A1-A1′ of FIG. 1.

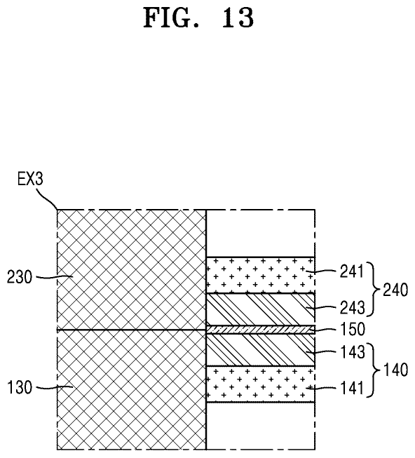

FIG. 13 is an enlarged cross-sectional view of a region EX3 of FIG. 12.

Referring to FIGS. 11 to 13, the semiconductor device 3000 may include a first stack structure SS1 and a second stack structure SS2. In providing description with reference to FIGS. 11 to 13, a first bonding layer 140 and a second bonding layer 240 may be (substantially) the same as the first bonding layer 140 and the second bonding layer 240 each described above with reference to FIGS. 1 to 7.

In embodiments, the first stack structure SS1 may include a first substrate 3110, a plurality of semiconductor patterns 3120 disposed on the first substrate 3110, a plurality of bit lines BL, a plurality of word lines WL, and a cell capacitor CAP.

In embodiments, the first substrate 3110 may include, for example, Si, Ge, and/or SiGe. In embodiments, the first substrate 3110 may include an SOI substrate or a GeOI substrate.

In embodiments, the plurality of semiconductor patterns 3120 may extend in a first horizontal direction X and may be disposed apart from one another in a vertical direction (e.g., a vertical direction Z), on the first substrate 3110. The plurality of semiconductor patterns 3120 may include an undoped semiconductor material or a doped semiconductor material. In some embodiments, the plurality of semiconductor patterns 3120 may include polysilicon. In some embodiments, the plurality of semiconductor patterns 3120 may include amorphous metal oxide, polycrystalline metal oxide, and/or a combination of amorphous metal oxide and polycrystalline metal oxide.

In embodiments, the plurality of semiconductor patterns 3120 may have a line shape or a bar shape extending in the first horizontal direction X. In embodiments, each of the plurality of semiconductor patterns 3120 may include a channel region 3120A, and a first impurity region 3120S and a second impurity region 3120D arranged in the first horizontal direction X with the channel region 3120A therebetween. The first impurity region 3120S may be (electrically) connected to the bit line BL, and the second impurity region 3120D may be (electrically) connected to the cell capacitor CAP.

In embodiments, the plurality of word lines WL may include a doped semiconductor material (doped silicon, doped germanium, etc.), conductive metal nitride (nitride titanium, nitride tantalum, etc.), metal (tungsten, titanium, tantalum, etc.), and/or a metal-semiconductor compound (tungsten silicide, cobalt silicide, titanium silicide, etc.).

In embodiments, the gate insulation layer 3130 may be disposed between the word line WL and the semiconductor pattern 3120. The gate insulation layer 3130 may include a high-k dielectric material and a ferroelectric material each having a dielectric constant which is greater (higher) than that of silicon oxide.

In embodiments, the plurality of bit lines BL may extend in the vertical direction Z and may be disposed apart from one another in a second horizontal direction Y, on the first substrate 3110. The plurality of bit lines BL may include, for example, a doped semiconductor material, conductive metal nitride, metal, and/or a metal-semiconductor compound.

In embodiments, the cell capacitor CAP may include a first electrode EL1, a capacitor dielectric layer DL, and a second electrode EL2. The first electrode EL1 may extend in the first horizontal direction X and may be disposed apart from an adjacent first electrode EL1 in the vertical direction Z. The first electrode EL1 may include an internal space extending in the first horizontal direction X, and the internal space may be (at least partially) filled by the capacitor dielectric layer DL and the second electrode EL2. The second electrode EL2 may (at least partially) fill the internal space of the first electrode EL1, and the capacitor dielectric layer DL may be disposed between the internal space of the first electrode EL1 and the second electrode EL2.

In embodiments, the first electrode EL1 and the second electrode EL2 may include, for example, conductive metal nitride such as a doped semiconductor material, titanium nitride, tantalum nitride, niobium nitride, and/or tungsten nitride, metal such as ruthenium, iridium, titanium, and/or tantalum, and/or conductive metal oxide such as iridium oxide and/or niobium oxide.

In embodiments, a plate electrode PP may be disposed to extend in the vertical direction Z and the second horizontal direction Y on one side of the cell capacitor CAP. The second electrode EL2 of the cell capacitor CAP may be electrically connected to the plate electrode PP, and for example, a plurality of second electrodes EL2 disposed apart from one another in the vertical direction Z and a plurality of second electrodes EL2 disposed apart from one another in the second horizontal direction Y may be (electrically) connected to the plate electrode PP in common.

In embodiments, the mold insulation layer 3122 may be disposed between two adjacent semiconductor patterns 3120 disposed apart from each other in the vertical direction Z, between two adjacent word lines WL disposed apart from each other in the vertical direction Z, and between two adjacent first electrodes EL1 disposed apart from each other in the vertical direction Z. The mold insulation layer 3122 may be disposed between two adjacent bit lines BL disposed apart from each other in the second horizontal direction Y. The mold insulation layer 3122 may include, for example, silicon oxide, silicon oxynitride, silicon nitride, carbon-containing silicon oxide, carbon-containing silicon oxynitride, carbon-containing silicon nitride, and/or a combination thereof.

In embodiments, the first stack structure SS1 may include an upper wiring structure 3150. The upper wiring structure 3150 may include a wiring layer 3152, a via 3154, and an insulation layer 3156. The upper wiring structure 3150 may further include a contact 3158 electrically connected to the bit line BL, the word line WL, and the plate electrode PP.

In embodiments, a plurality of first bonding pads 130 and a first bonding layer 140 on (e.g., covering or overlapping in the vertical direction Z) the first bonding pads 130 may be disposed on the insulation layer 3156. The first bonding layer 140 may include a first lower bonding layer 141 and a first upper bonding layer 143. The first lower bonding layer 141 may be on (e.g., cover or overlap in the vertical direction Z) an upper surface of the insulation layer 3156, and the first upper bonding layer 143 may be on (e.g., cover or overlap in the vertical direction Z) an upper surface of the first lower bonding layer 141.

In embodiments, the first lower bonding layer 141 and the first upper bonding layer 143 may include different materials (e.g., materials having different compositions (e.g., different element ratios)). The first lower bonding layer 141 and the first upper bonding layer 143 may include SiCN, and the first lower bonding layer 141 and the first upper bonding layer 143 may differ in composition (e.g., element ratio). For example, the first lower bonding layer 141 may include C-rich SiCN, and the first upper bonding layer 143 may include N-rich SiCN.

In embodiments, the plurality of first bonding pads 130 may extend into (e.g., pass through) the first bonding layer 140. The plurality of first bonding pads 130 may be (at least partially) surrounded by the first bonding layer 140. The plurality of first bonding pads 130 may include, for example, copper.

In embodiments, the second stack structure SS2 may include a second substrate 3310, a peripheral circuit transistor 3320 disposed on the second substrate 3310, a front-side wiring structure 3330 on (covering or overlapping in the vertical direction Z) the peripheral circuit transistor 3320 on an upper surface of the second substrate 3310, and a backside wiring structure 3340 disposed on a lower surface of the second substrate 3310. The front-side wiring structure 3330 may include a wiring layer 3332, a via 3334, and an insulation layer 3336, and the backside wiring structure 3340 may include a wiring layer 3342, a via 3344, and an insulation layer 3346.

In embodiments, a plurality of second bonding pads 230 and a second bonding layer 240 on (e.g., covering, overlapping, or extending around) the second bonding pads 230 may be disposed on the insulation layer 3346. The second bonding layer 240 may include a second lower bonding layer 241 and a second upper bonding layer 243. The second lower bonding layer 241 may be on (e.g., cover or overlap in the vertical direction Z) a lower surface of the insulation layer 3346, and the second upper bonding layer 243 may be on (e.g., cover or overlap in the vertical direction Z) a lower surface of the second lower bonding layer 241.

In embodiments, the second lower bonding layer 241 and the second upper bonding layer 243 may include different materials (e.g., materials having different compositions (e.g., different element ratios). The second lower bonding layer 241 and the second upper bonding layer 243 may include SiCN, and the second lower bonding layer 241 and the second upper bonding layer 243 may differ in composition (e.g., element ratio). For example, the second lower bonding layer 241 may include C-rich SiCN, and the second upper bonding layer 243 may include N-rich SiCN.

In embodiments, the plurality of second bonding pads 230 may extend into (e.g., pass through) the second bonding layer 240. The plurality of second bonding pads 230 may be (at least partially) surrounded by the second bonding layer 240. The plurality of second bonding pads 230 may include, for example, copper.

In embodiments, the first stack structure SS1 may contact the second stack structure SS2. In detail, the first bonding layer 140 of the first stack structure SS1 and the second bonding layer 240 of the second stack structure SS2 may be disposed to overlap each other in a vertical direction (e.g., the vertical direction Z) and may be adhered to each other. The first bonding pads 130 of the first stack structure SS1 and the second bonding pads 230 of the second stack structure SS2 may be disposed to overlap each other in the vertical direction (e.g., the vertical direction Z) and may be adhered to each other. The first stack structure SS1 and the second stack structure SS2 may be bonded to each other by an HCB process. The first stack structure SS1 may be electrically connected and bonded to the second stack structure SS2 by the first bonding pads 130 and the second bonding pads 230. In this case, a bonding interface layer 150 may be disposed between the first bonding layer 140 and the second bonding layer 240 (in the vertical direction Z). The bonding interface layer 150 may include, for example, oxide and may be less (thinner) in thickness than the first bonding layer 140 and the second bonding layer 240.

In embodiments, the peripheral circuit transistor 3320 may include a gate electrode 3322 and a gate insulation layer 3324, which are disposed in an active region of the second substrate 3310. In embodiments, the peripheral circuit transistor 3320 may include a plurality of sense amplifiers, and the sense amplifiers may be electrically connected to bit lines BL included in the first stack structure SS1. The peripheral circuit transistor 3320 may include sub word line drivers, and the sub word line drivers may be electrically connected to word lines WL included in the first stack structure SS1.

In embodiments, the second stack structure SS2 may further include a through via 3350 extending into (e.g., passing through) the second substrate 3310. The wiring layer 3332 included in the front-side wiring structure 3330 may be electrically connected to the wiring layer 3342 included in the backside wiring structure 3340 by using the through via 3350.

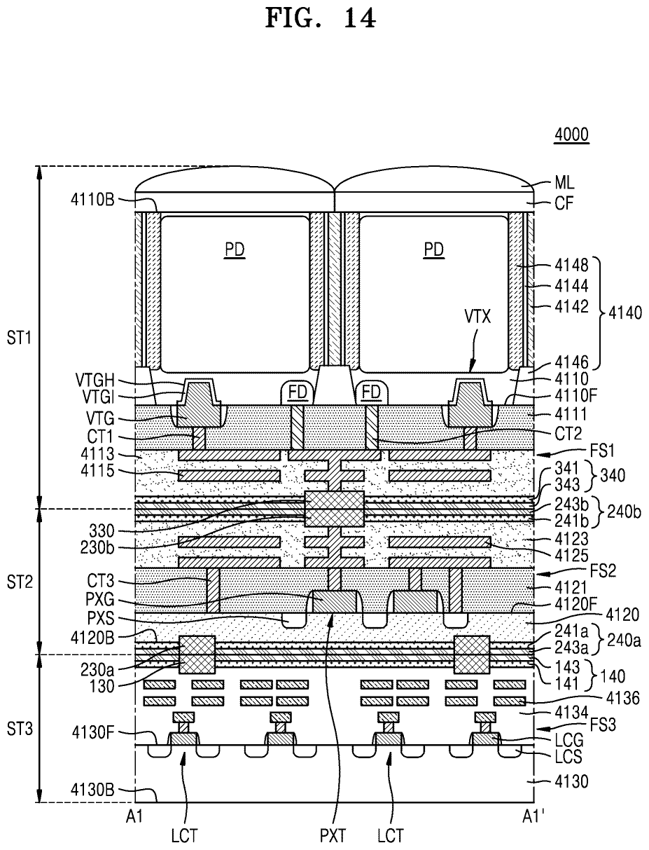

FIG. 14 is a cross-sectional view illustrating a schematic configuration of a semiconductor device 4000 according to some embodiments.

Referring to FIG. 14, the semiconductor device 4000 may be a stack-type image sensor where a first stack structure ST1, a second stack structure ST2, and a third stack structure ST3 are stacked in a vertical direction. In providing description with reference to FIG. 14, a first bonding layer 140, a second bonding layer 240a may be (substantially) the same as the first bonding layer 140 and the second bonding layer 240 each described above with reference to FIGS. 1 to 7, respectively. A third bonding layer 240b and a fourth bonding layer 340 may be (substantially) the same as the first bonding layer 140 and the second bonding layer 240 each described above with reference to FIGS. 1 to 7, respectively.

The first stack structure ST1 may include a first semiconductor substrate 4110 including a front-side surface 4110F and a backside surface 4110B, a photodiode region PD and a floating diffusion region FD each formed in the first semiconductor substrate 4110, a first transfer transistor VTG disposed on the front-side surface 4110F of the first semiconductor substrate 4110, a first front-side structure FS1, and a color filter CF and a microlens ML each disposed on the backside surface 4110B of the first semiconductor substrate 4110.

The second stack structure ST2 may include a second semiconductor substrate 4120 including a front-side surface 4120F and a backside surface 4120B, a pixel transistor PXT disposed on the front-side surface 4120F of the second semiconductor substrate 4120, a second front-side structure FS2, and a backside structure (not shown) disposed on the backside surface 4120B of the second semiconductor substrate 4120.

The third stack structure ST3 may include a third semiconductor substrate 4130 including a front-side surface 4130F, and a logic transistor LCT and a third front-side structure FS3 each disposed on the front-side surface 4130F of the third semiconductor substrate 4130.

In embodiments, the first, second, and third semiconductor substrates 4110, 4120, and 4130 may include a P-type semiconductor substrate. For example, at least one of the first, second, and third semiconductor substrates 4110, 4120, and 4130 may include a P-type silicon substrate. In embodiments, at least one of the first, second, and third semiconductor substrates 4110, 4120, and 4130 may include a P-type bulk substrate and a P-type or N-type epi layer grown thereon, but is not limited thereto and in other embodiments, at least one of the first, second, and third semiconductor substrates 4110, 4120, and 4130 may include an N-type bulk substrate and a P-type or N-type epi layer grown thereon.

A PD isolation pattern (pixel isolation structure) 4140 may be disposed in the first semiconductor substrate 4110 of the first stack structure ST1. A plurality of pixels may be defined by the PD isolation pattern 4140. The PD isolation pattern 4140 may include a conductive layer 4142, an insulation liner 4144, and an upper insulation layer 4146. The conductive layer 4142 may be disposed in a pixel trench 4140T extending into (e.g., passing through) the first semiconductor substrate 4110. The insulation liner 4144 may be disposed on an inner wall of the pixel trench 4140T extending into (e.g., passing through) the first semiconductor substrate 4110 and may be disposed between the conductive layer 4142 and the first semiconductor substrate 4110. The upper insulation layer 4146 may be disposed in a portion of the pixel trench 4140T adjacent to the front-side surface 4110F of the first semiconductor substrate 4110.

In embodiments, the PD isolation pattern 4140 may extend into (e.g., pass through) the first semiconductor substrate 4110. For example, the PD isolation pattern 4140 may be a front-side deep trench isolation (FDTI). Unlike the illustration, the PD isolation pattern 4140 may not pass through the first semiconductor substrate 4110. For example, the PD isolation pattern 4140 may be a backside deep trench isolation (BDTI).

In embodiments, the conductive layer 4142 may include, for example, doped polysilicon, metal, metal silicide, metal nitride, and/or a metal-containing film. The insulation liner 4144 may include an insulating material such as silicon oxide, silicon nitride, and/or silicon oxynitride. The upper insulation layer 4146 may include an insulating material such as silicon oxide, silicon nitride, and/or silicon oxynitride.

In embodiments, a plurality of photodiode regions (photoelectric conversion regions) PD may be disposed in the first stack structure ST1. The photodiode region PD may be a region doped with n-type impurities. For example, the photodiode region PD may have an impurity concentration difference between an upper portion and a lower portion thereof to have a potential slope. The photodiode region PD may be formed as a type where a plurality of impurity regions are stacked in a vertical direction.

In some embodiments, a liner region 4148 extending around (e.g., at least partially surrounding) each of the plurality of photodiode regions PD may be disposed in a portion of the first semiconductor substrate 4110. The liner region 4148 may be disposed between the PD isolation pattern 4140 and the photodiode region PD and may be a region doped with p-type impurities.

In embodiments, the floating diffusion region FD may be disposed in an internal region of the first semiconductor substrate 4110 adjacent to the front-side surface 4110F of the first semiconductor substrate 4110. The floating diffusion region FD may be a region which stores an electric charge transferred from the photodiode region PD. A ground region (not shown) may be disposed in the internal region of the first semiconductor substrate 4110 adjacent to the front-side surface 4110F of the first semiconductor substrate 4110.

In embodiments, a first vertical transfer gate VTG may be disposed on the front-side surface 4110F of the first semiconductor substrate 4110. The first vertical transfer gate VTG may be a transfer gate configuring the first vertical transfer transistor VTX. In this case, the first vertical transfer gate VTG may be a vertical transfer gate.

In embodiments, a transfer gate insulation layer VTGI may be disposed on an inner wall of a transfer gate trench VTGH. The transfer gate insulation layer VTGI may be disposed to have a relatively uniform thickness between the first vertical transfer gate VTG and the first semiconductor substrate 4110. The first vertical transfer gate VTG may include, for example, doped polysilicon, metal, metal silicide, metal nitride, and/or a metal-containing film.

In embodiments, the first vertical transfer gate VTG may be disposed apart from the floating diffusion region FD in a horizontal direction. The first transfer transistor VTX may transfer an electric charge, generated in the photodiode region PD, to the floating diffusion region FD. The first vertical transfer transistor VTX may electrically connect the photodiode region PD to the floating diffusion region FD.

A first front-side structure FS1 may be disposed on the front-side surface 4110F of the first semiconductor substrate 4110 of the first stack structure ST1. The first stack structure ST1 may include a first insulation layer 4111 and a second insulation layer 4113, which are disposed on the front-side surface 4110F of the first semiconductor substrate 4110. In embodiments, the first insulation layer 4111 and the second insulation layer 4113 may include, for example, silicon oxide, silicon nitride, silicon oxynitride, and/or silicon carbon nitride. For example, the first insulation layer 4111 may include silicon oxide, and the second insulation layer 4113 may include silicon nitride.

In embodiments, the first insulation layer 4111 may be on (e.g., cover or overlap) the first vertical transfer gate VTG disposed on the front-side surface 4110F of the first semiconductor substrate 4110. The first front-side structure FS1 may include a first contact CT1 and a second contact CT2, each extending into (e.g., passing through) the first insulation layer 4111, and a first wiring structure 4115. The first wiring structure 4115 may be disposed in the second insulation layer 4113. The first wiring structure 4115 may include a plurality of conductive vias and a plurality of wiring layers. The first wiring structure 4115 may be electrically connected to each of the first contact CT1, the second contact CT2, and the first vertical transfer transistor VTX. The first contact CT1 may extend into (e.g., pass through) the first insulation layer 4111 and may be electrically connected to the first vertical transfer gate VTG. The second contact CT2 may extend into (e.g., pass through) the first insulation layer 4111 and may be electrically connected to the floating diffusion region FD.

In embodiments, a second front-side structure FS2 may be disposed on the front-side surface 4120F of the second semiconductor substrate 4120 of the second stack structure ST2. The second stack structure ST2 may include a third insulation layer 4121 and a fourth insulation layer 4123, which are disposed on the front-side surface 4120F of the second semiconductor substrate 4120.

In embodiments, the third insulation layer 4121 may be on (e.g., cover or overlap) the pixel transistor PXT disposed on the front-side surface 4120F of the second semiconductor substrate 4120. The second front-side structure FS2 may include a third contact CT3 extending into (e.g., passing through) the third insulation layer 4121 and a second wiring structure 4125 disposed in the fourth insulation layer 4123. The second wiring structure 4125 may include a plurality of conductive vias and a plurality of wiring layers. The third contact CT3 and the second wiring structure 4125 may be disposed to be electrically connected to the pixel transistor PXT. In embodiments, the pixel transistor PXT may include a reset transistor, a selection transistor, and/or a source follower transistor.

In embodiments, a backside structure may be disposed on a backside surface of the second semiconductor substrate 4120 of the second stack structure ST2. The backside structure may include an insulation layer disposed on the backside surface of the second semiconductor substrate 4120.

A third front-side structure FS3 may be disposed on a front-side surface 4130F of the third semiconductor substrate 4130 of the third stack structure ST3. The third front-side structure FS3 may include a third wiring structure 4136 and a cover insulation layer 4134. The third wiring structure 4136 may include a plurality of conductive vias and a plurality of wiring layers. The third wiring structure 4136 may be disposed to be electrically connected to a logic transistor LCT. The third stack structure ST3 may include the logic transistor LCT disposed on a front-side surface 4130F of the third semiconductor substrate 4130, and the logic transistor LCT may include a logic gate LCG and a source/drain region LCS.

In embodiments, the first bonding layer 140 may be on (e.g., cover or overlap in the vertical direction) an upper surface of the cover insulation layer 4134 of the third stack structure ST3 and may comprise (or consist of) a double layer (e.g., two sub-layers). The first bonding layer 140 may include a first lower bonding layer 141 and a first upper bonding layer 143. The first lower bonding layer 141 may be on (e.g., cover or overlap in the vertical direction) an upper surface of the cover insulation layer 4134, and the first upper bonding layer 143 may be on (e.g., cover or overlap in the vertical direction) an upper surface of the first lower bonding layer 141.

In embodiments, the first lower bonding layer 141 and the first upper bonding layer 143 may include different materials (e.g., materials having different compositions (e.g., different element ratios)). The first lower bonding layer 141 and the first upper bonding layer 143 may include SiCN, and the first lower bonding layer 141 and the first upper bonding layer 143 may differ in composition (e.g., element ratio). For example, the first lower bonding layer 141 may include C-rich SiCN, and the first upper bonding layer 143 may include N-rich SiCN.

In embodiments, the plurality of first bonding pads 130 may extend into (e.g., pass through) the first bonding layer 140. The plurality of first bonding pads 130 may be (at least partially) surrounded by the first bonding layer 140. The plurality of first bonding pads 130 may include, for example, copper.

In embodiments, second bonding pads 230a and a second bonding layer 240a on (e.g., covering or extending around) the second bonding pads 230a may be disposed on a backside surface 4120B of the second semiconductor substrate 4120. The second bonding layer 240a may include a second lower bonding layer 241a and a second upper bonding layer 243a. The second lower bonding layer 241a may be on (e.g., cover or overlap in the vertical direction) the backside surface 4120B of the second semiconductor substrate 4120, and the second upper bonding layer 243a may be on (e.g., cover or overlap) a lower surface of the second lower bonding layer 241a. In this case, a backside structure may be disposed between the second semiconductor substrate 4120 and the second bonding layer 240a.

In embodiments, the second lower bonding layer 241a and the second upper bonding layer 243a may include different materials (e.g., materials having different compositions (e.g., different element ratios)). The second lower bonding layer 241a and the second upper bonding layer 243a may include SiCN, and the second lower bonding layer 241a and the second upper bonding layer 243a may differ in composition (e.g., element ratio). For example, the second lower bonding layer 241a may include C-rich SiCN, and the second upper bonding layer 243a may include N-rich SiCN.

In embodiments, the plurality of second bonding pads 230a may extend into (e.g., pass through) the second bonding layer 240a. The plurality of second bonding pads 230a may be (at least partially) surrounded by the second bonding layer 240a. The plurality of second bonding pads 230a may include, for example, copper.

In embodiments, the third stack structure ST3 may be bonded to the second stack structure ST2. In detail, the first bonding layer 140 of the third stack structure ST3 and the second bonding layer 240a of the second stack structure ST2 may be disposed to overlap each other in a vertical direction and may be adhered to each other. The first bonding pads 130 of the third stack structure ST3 and the second bonding pads 230a of the second stack structure ST2 may be disposed to overlap each other in the vertical direction and may be adhered to each other. The third stack structure ST3 and the second stack structure ST2 may be bonded to each other by an HCB process. The third stack structure ST3 may be electrically connected and bonded to the second stack structure ST2 by the first bonding pads 130 and the second bonding pads 230a.

The third bonding layer 240b may be on (e.g., cover or overlap in the vertical direction) an upper surface of the fourth insulation layer 4123 of the second stack structure ST2 and may comprise (or consist of) a double layer (e.g., two sub-layers). The third bonding layer 240b may include a third lower bonding layer 241b and a third upper bonding layer 243b. The third lower bonding layer 241b may be on (e.g., cover or overlap in the vertical direction) an upper surface of the fourth insulation layer 4123, and the third upper bonding layer 243b may be on (e.g., cover or overlap in the vertical direction) an upper surface of the third lower bonding layer 241a. In this case, the third lower bonding layer 241b may include C-rich SiCN, and the third upper bonding layer 243b may include N-rich SiCN.

In embodiments, the plurality of third bonding pads 230b may extend into (e.g., pass through) the third bonding layer 240b. The plurality of third bonding pads 230b may be (at least partially) surrounded by the third bonding layer 240b. The plurality of third bonding pads 230b may include, for example, copper.

In embodiments, the fourth bonding layer 340 may be on (e.g., cover or overlap in the vertical direction) a lower surface of the second insulation layer 4113 of the first stack structure ST1 and may comprise (or consist of) a double layer (e.g., two sub-layers). The fourth bonding layer 340 may include a fourth lower bonding layer 341 and a fourth upper bonding layer 343. The fourth lower bonding layer 341 may be on (e.g., cover or overlap in the vertical direction) a lower surface of the second insulation layer 4113, and the fourth upper bonding layer 343 may be on (e.g., cover or overlap in the vertical direction) a lower surface of the fourth lower bonding layer 341. In this case, the fourth lower bonding layer 341 may include C-rich SiCN, and the fourth upper bonding layer 343 may include N-rich SiCN.

In embodiments, the plurality of fourth bonding pads 330 may extend into (e.g., pass through) the fourth bonding layer 340. The plurality of fourth bonding pads 330 may be (at least partially) surrounded by the fourth bonding layer 340. The plurality of fourth bonding pads 330 may include, for example, copper.

In embodiments, the second stack structure ST2 may be bonded to the first stack structure ST1. In detail, the third bonding layer 240b of the second stack structure ST2 and the fourth bonding layer 340 of the first stack structure ST1 may be disposed to overlap each other in a vertical direction and may be adhered to each other. The third bonding pads 230b of the second stack structure ST2 and the fourth bonding pads 330 of the first stack structure ST1 may be disposed to overlap each other in the vertical direction and may be adhered to each other. The second stack structure ST2 and the first stack structure ST1 may be bonded to each other by an HCB process. The first stack structure ST1 may be electrically connected and bonded to the second stack structure ST2 by the third bonding pads 230b and the fourth bonding pads 330.

Hereinabove, example embodiments have been described in the drawings and the specification. Embodiments have been described by using the terms described herein, but this has been merely used for describing the inventive concept and has not been used for limiting a meaning or limiting the scope of the inventive concept defined in the following claims. Therefore, it may be understood by those of ordinary skill in the art that various modifications and other equivalent embodiments may be implemented from the inventive concept.

While the inventive concept has been particularly shown and described with reference to embodiments thereof, it will be understood that various changes in form and details may be made therein without departing from the scope of the following claims.

What is claimed is:

1. A semiconductor device comprising:
a first stack structure that includes a first substrate, a first bonding layer on the first substrate, and a first bonding pad that extends into the first bonding layer; and
a second stack structure on the first stack structure, wherein the second stack structure includes a second substrate, a second bonding layer on the second substrate, and a second bonding pad that extends into the second bonding layer,
wherein the first bonding layer includes a first lower bonding layer and a first upper bonding layer that extend around the first bonding pad,
wherein the second bonding layer includes a second lower bonding layer and a second upper bonding layer that extend around the second bonding pad,
wherein the first bonding layer of the first stack structure is in contact with the second bonding layer of the second stack structure, and
wherein the first bonding pad of the first stack structure is in contact with the second bonding pad of the second stack structure.

2. The semiconductor device of claim 1, wherein the first upper bonding layer is on the first substate,
wherein the first lower bonding layer is between the first upper bonding layer and the first substrate in a vertical direction that is perpendicular to an upper surface of the first substrate,
wherein the second upper bonding layer is on the second substate, and
wherein the second lower bonding layer is between the second upper bonding layer and the second substrate in the vertical direction.

3. The semiconductor device of claim 2, wherein the first lower bonding layer and the second lower bonding layer each comprise C-rich SiCN,
wherein the first upper bonding layer and the second upper bonding layer comprise N-rich SiCN,
wherein a carbon ratio of the C-rich SiCN is greater than a carbon ratio of the N-rich SiCN, and
wherein a nitrogen ratio of the N-rich SiCN is greater than a nitrogen ratio of the C-rich SiCN.

4. The semiconductor device of claim 2, wherein the first lower bonding layer and the first upper bonding layer comprise a first material and a second material, respectively,
wherein the first material and the second material have different compositions from each other,
wherein the second lower bonding layer and the second upper bonding layer comprise a third material and a fourth material, respectively, and
wherein the third material and the fourth material have different compositions from each other.

5. The semiconductor device of claim 2, wherein a thickness of the first lower bonding layer in the vertical direction is greater than a thickness of the first upper bonding layer in the vertical direction, and
wherein a thickness of the second lower bonding layer in the vertical direction is greater than a thickness of the second upper bonding layer in the vertical direction.

6. The semiconductor device of claim 1, further comprising a bonding interface layer between the first bonding layer and the second bonding layer in a vertical direction that is perpendicular to an upper surface of the first substrate.

7. The semiconductor device of claim 1, wherein an upper surface of the first bonding layer and an upper surface of the first bonding pad are coplanar with each other, and
wherein a lower surface of the second bonding layer and a lower surface of the second bonding pad are coplanar with each other.

8. The semiconductor device of claim 1, wherein the first stack structure further comprises a first wiring structure between the first substrate and the first bonding layer in a vertical direction that is perpendicular to an upper surface of the first substrate,
wherein the first wiring structure includes a plurality of first wiring layers and a plurality of first insulation layers respectively on the plurality of first wiring layers,
wherein the second stack structure further comprises a second wiring structure between the second substrate and the second bonding layer in the vertical direction, and
wherein the second wiring structure includes a plurality of second wiring layers and a plurality of second insulation layers respectively on the plurality of second wiring layers.

9. A semiconductor device comprising:
a first stack structure and a second stack structure on the first stack structure,
wherein the first stack structure comprises:
a first substrate;
a first wiring structure that is on an upper surface of the first substrate and includes a plurality of first wiring layers and a plurality of first insulation layers that are respectively on the plurality of first wiring layers;
a first bonding layer that includes a first lower bonding layer and a first upper bonding layer, wherein the first lower bonding layer is on an upper surface of the first wiring structure, and the first upper bonding layer is on an upper surface of the first lower bonding layer; and
a first bonding pad that extends into the first bonding layer,
wherein the second stack structure comprises:
a second substrate;
a second wiring structure that is on a lower surface of the second substrate and includes a plurality of second wiring layers and a plurality of second insulation layers that are respectively on the plurality of second wiring layers;
a second bonding layer that includes a second lower bonding layer and a second upper bonding layer, wherein the second lower bonding layer is on a lower surface of the second wiring structure, and the second upper bonding layer is on a lower surface of the second lower bonding layer; and
a second bonding pad that extends into the second bonding layer,
wherein the first upper bonding layer of the first stack structure is in contact with the second upper bonding layer of the second stack structure, and
wherein the first bonding pad of the first stack structure is in contact with the second bonding pad of the second stack structure.

10. The semiconductor device of claim 9, wherein the first lower bonding layer and the second lower bonding layer comprise C-rich SiCN,
wherein the first upper bonding layer and the second upper bonding layer comprise N-rich SiCN,
wherein a carbon ratio of the C-rich SiCN is greater than a carbon ratio of the N-rich SiCN, and wherein a nitrogen ratio of the N-rich SiCN is greater than a nitrogen ratio of the C-rich SiCN.

11. The semiconductor device of claim 9, wherein the first lower bonding layer and the first upper bonding layer comprise a first material and a second material, respectively,
wherein the first material and the second material have different compositions from each other,
wherein the second lower bonding layer and the second upper bonding layer comprise a third material and a fourth material, respectively, and
wherein the third material and the fourth material have different compositions from each other.

12. The semiconductor device of claim 9, further comprising:
a third stack structure that is on the second stack structure and includes: a third substrate; a third wiring structure that is on a lower surface of the third substrate and includes a plurality of third wiring layers and a plurality of third insulation layers that are respectively on the plurality of third wiring layers; a third bonding layer that includes a third lower bonding layer on a lower surface of the third wiring structure and a third upper bonding layer on a lower surface of the third lower bonding layer; and a third bonding pad that extends into the third bonding layer,
wherein the second stack structure further comprises:
a fourth bonding layer that includes a fourth lower bonding layer on an upper surface of the second wiring structure and a fourth upper bonding layer on an upper surface of the fourth lower bonding layer; and
a fourth bonding pad that extends into the fourth bonding layer, and
wherein the fourth upper bonding layer of the second stack structure is in contact with the third upper bonding layer of the third stack structure, and
wherein the fourth bonding pad of the second stack structure is in contact with the third bonding pad of the third stack structure.

13. The semiconductor device of claim 12, wherein the third lower bonding layer and the fourth lower bonding layer comprise C-rich SiCN,
wherein the third upper bonding layer and the fourth upper bonding layer comprise N-rich SiCN,
wherein a carbon ratio of the C-rich SiCN is greater than a carbon ratio of the N-rich SiCN, and
wherein a nitrogen ratio of the N-rich SiCN is greater than a nitrogen ratio of the C-rich SiCN.

14. The semiconductor device of claim 13, wherein the third stack structure further comprises a photodiode region in the third substrate, a floating diffusion region that is configured to store electric charge transferred from the photodiode region, and a first transfer gate that is spaced apart from the floating diffusion region in a horizontal direction that is parallel with the lower surface of the third substrate,
wherein the second stack structure further comprises a pixel gate that is on the second substrate and electrically connected to the floating diffusion region, and
wherein the first stack structure further comprises a logic transistor that is configured to provide a signal to the pixel gate and the first transfer gate.

15. The semiconductor device of claim 9, wherein the first stack structure further comprises a plurality of memory cells, and
wherein the second stack structure further comprises a plurality of peripheral circuit transistors.

16. The semiconductor device of claim 15, wherein the first wiring structure further comprises:
a plurality of gate electrodes and a plurality of mold insulation layers alternately arranged in a vertical direction on the upper surface of the first substrate, wherein the vertical direction is perpendicular to the upper surface of the first substrate;
a channel structure that extends into the plurality of gate electrodes in the vertical direction; and
a plurality of contact plugs that are electrically connected to the plurality of gate electrodes.

17. The semiconductor device of claim 15, wherein the first wiring structure further comprises:
a semiconductor pattern that includes a channel region, a first impurity region, and a second impurity region, wherein the channel region is between the first impurity region and the second impurity region in a first horizontal direction that is parallel with the upper surface of the first substrate, and wherein the semiconductor pattern extends in the first horizontal direction on the first substrate and is spaced apart from the first substrate in a vertical direction that is perpendicular to the upper surface of the first substrate;
a word line that extends around the semiconductor pattern and extends in a second horizontal direction that is parallel with the upper surface of the first substrate and intersects the first horizontal direction;
a bit line that is electrically connected to the first impurity region of the semiconductor pattern and extends in the vertical direction; and
a cell capacitor that is electrically connected to the second impurity region of the semiconductor pattern.

18. A method of manufacturing a semiconductor device, the method comprising:
forming, on a first substrate, a first lower bonding layer that includes a first material and a first upper bonding layer that includes a second material on the first lower bonding layer, wherein the first material has a first composition that is different from a second composition of the second material;
forming a first opening that extends into the first lower bonding layer and the first upper bonding layer;
forming a first metal layer in the first opening and on the first upper bonding layer;
planarizing the first metal layer to form a first bonding pad;
forming, on a second substrate, a second lower bonding layer that includes a third material and a second upper bonding layer that includes a fourth material on the second lower bonding layer, wherein the third material has a third composition that is different from a fourth composition of the fourth material;
forming a second opening that extends into the second lower bonding layer and the second upper bonding layer;
forming a second metal layer in the second opening and on the second upper bonding layer;
planarizing the second metal layer to form a second bonding pad; and
bonding the first upper bonding layer and first bonding pad to the second upper bonding layer and the second bonding pad.

19. The method of claim 18, wherein the first material and the third material comprise C-rich SiCN,
wherein the second material and the fourth material comprise N-rich SiCN,
wherein a carbon ratio of the C-rich SiCN is greater than a carbon ratio of the N-rich SiCN, and
wherein a nitrogen ratio of the N-rich SiCN is greater than a nitrogen ratio of the C-rich SiCN.

20. The method of claim 18, wherein the planarizing the first metal layer comprises forming a first coplanar surface formed by an upper surface of the first upper bonding layer and an upper surface of the first bonding pad, and
wherein the planarizing the second metal layer comprises forming a second coplanar surface formed by an upper surface of the second upper bonding layer and an upper surface of the second bonding pad.
